(19) United States
(12) Patent Application Publication
(10) Pub. No.: US 2014/0219000 A1
(43) Pub. Date: Aug. 7, 2014

(54) OTP CELL ARRAY INCLUDING PROTECTED AREA, SEMICONDUCTOR MEMORY DEVICE INCLUDING THE SAME, AND METHOD OF PROGRAMMING THE SAME

(71) Applicant: Samsung Electronics Co., Ltd., Suwon-si (KR)

(72) Inventors: Chi-Sung OH, Suwon-si (KR); Chul-Sung PARK, Seoul (KR); Nak-Won HEO, Hwaseong-si (KR); Dong-Hyun SOHN, Hwaseong-si (KR)

(73) Assignee: Samsung Electronics Co., Ltd., Suwon-si (KR)

(21) Appl. No.: 14/107,199

(22) Filed: Dec. 16, 2013

(30) Foreign Application Priority Data
Feb. 5, 2013 (KR) 10-2013-0013027

(51) Int. Cl. G11C 17/16; G11C 29/52; G06F 12/14

(52) U.S. Cl. CPC G11C 17/16; G06F 12/1458; G11C 29/52
USPC 365/96

(57) ABSTRACT

A method of programming a memory device including a one-time programmable (OTP) cell array configured to include at least one of a protected area and a programmable area are disclosed. The method includes receiving a fuse-program command to initiate a fuse-programming operation; checking whether the programmable area exists in the OTP cell array, terminating the fuse-programming operation when the OTP cell array does not include the programmable area, performing a fuse-programming operation on the programmable area when the OTP cell array includes the programmable area thereby programming fuses to create a fuse-programmed area; setting the fuse-programmed area of the OTP cell array as the protected area.

### CROSS-REFERENCE TO RELATED APPLICATION

This application claims priority under 35 U.S.C. §119 to Korean Patent Application No. 10-2013-0013027 filed on Feb. 5, 2013, the entire contents of which are incorporated herein by reference in their entirety.

### BACKGROUND

Embodiments of the disclosure relate to a semiconductor memory device, and particularly, to a semiconductor memory device including a one-time programmable (OTP) cell array and a method of programming the OTP cell array.

A semiconductor memory device may include a one-time programmable (OTP) cell array to store information necessary for operating the semiconductor memory device. The OTP cell array may include an anti-fuse and/or an electric fuse. The electric fuse is a device that turns off when a certain condition is satisfied, and the anti-fuse is a device that turns on when a certain condition is satisfied. The anti-fuse or the electric fuse may be used to select an operation mode of the semiconductor memory device, or activate a redundancy array when defective cells are included in a memory cell array.

In some cases, users unintentionally perform re-programming of a set of anti-fuses that have already been once programmed. As a result, the data or program states stored from the original programming may be lost or corrupted. Accordingly, it is desirable to protect certain groups of anti-fuses from being reprogrammed.

### SUMMARY

Embodiments of the disclosure provide a method of programming a one-time programmable (OTP) cell array capable of setting a part of programmed fuse blocks as a protected area.

Embodiments of the disclosure also provide a semiconductor memory device including OTP cell array capable of setting a part of programmed fuse blocks as a protected area.

The technical objectives of the inventive concept are not limited to the above disclosure; other objectives may become apparent to those of ordinary skill in the art based on the following descriptions.

In accordance with an aspect of one embodiment, a method of programming a memory device including a one-time programmable (OTP) cell array configured to include at least one of a protected area and a programmable area is provided. The method includes receiving a fuse-program command to initiate a fuse-programming operation; checking whether the programmable area exists in the OTP cell array; terminating the fuse-programming operation when the OTP cell array does not include the programmable area; performing the fuse-programming on the programmable area when the OTP cell array includes the programmable area thereby programming fuses to create a fuse-programmed area; setting the fuse-programmed area of the OTP cell array as the protected area; and terminating the fuse-programming operation.

In accordance with an aspect of one embodiment, a semiconductor memory device includes a memory cell array configured to store data and an OTP cell array. The OTP cell array may include a protected area and a programmable area separate from the protected area, the OTP cell array configured to store a fail address corresponding to a defective memory cell of the memory cell array. The OTP cell array is configured to perform a fuse-programming operation on one or more blocks of the programmable area of the OTP cell array to create a fuse-programmed area, and set the fuse-programmed area of the OTP cell array as part of the protected area.

In accordance with an aspect of one embodiment, a method of programming a memory device including a one-time programmable (OTP) cell array is provided. The method includes reading an indicator that indicates whether a particular area of the OTP cell array is permitted to be written to or not; performing programming in the particular area when the indicator indicates that the particular area can be written to; and terminating a program operation without performing the programming when the indicator indicates that the particular area cannot be written to.

According to embodiments of the disclosure, an OTP cell array has a protected area and a programmable area separate from the protected area, and is configured to perform a fuse-programming operation on a programmable area of the OTP cell array, and sets the fuse-programmed area of the OTP cell array as a protected area.

Therefore, in the semiconductor memory device including the OTP cell array, a programmed area may be prevented from re-programming, and when programmable area exists in the OTP cell array, the programmable area may be determined as a protected area after the area is programmed. Additionally, the semiconductor memory device including the OTP cell array may efficiently use the OTP cell array because particular one or more blocks of the OTP cell array can be prevented from accessing.

### BRIEF DESCRIPTION OF THE DRAWINGS

Exemplary embodiments will be more clearly understood from the following detailed description taken in conjunction with the accompanying drawings in which:

FIG. 1 is an exemplary flowchart illustrating a method of programming an OTP cell array, in accordance with one embodiment;

FIG. 2 is an exemplary flowchart illustrating a method of programming an OTP cell array, in accordance with another embodiment;

FIG. 3 is an exemplary diagram illustrating a schematic structure of an OTP cell array that operates according to the method of programming the OTP cell array shown in FIG. 2;

FIG. 4 is an exemplary flowchart illustrating a method of programming an OTP cell array, in accordance with still another embodiment;

FIG. 5 is an exemplary diagram illustrating a schematic structure of an OTP cell array that operates according to the method of programming the OTP cell array shown in FIG. 4;

FIG. 6 is an exemplary block diagram illustrating a semiconductor memory device including an OTP cell array, in accordance with certain embodiments;

FIG. 7 is an exemplary diagram illustrating an anti-fuse array included in the semiconductor memory device of FIG. 6, in accordance with one embodiment;

FIG. 8 is an exemplary diagram illustrating a memory module including a semiconductor memory device, in accordance with certain embodiments;

FIGS. 9 and 10 are exemplary timing diagrams illustrating transmission of a fail address in the semiconductor memory device of FIG. 6, in accordance with certain embodiments;

FIG. 11 is a perspective view of an example of a stacked semiconductor device including a semiconductor memory device in accordance with certain embodiments;

FIG. 12 is a diagram of an example of a memory system including a semiconductor memory device in accordance with certain embodiments;

FIG. 13 is a block diagram of another example of a memory system including a semiconductor memory device in accordance with certain embodiments; and

FIG. 14 is a block diagram of an example of an electronic system including a semiconductor memory device in accordance with certain embodiments.

### DETAILED DESCRIPTION OF THE EMBODIMENTS

Example embodiments of the present disclosure are now will be described more fully hereinafter with reference to the accompanying drawings, in which embodiments of the disclosure are shown. This disclosure may, however, be embodied in many alternate forms and should not be construed as limited to the example embodiments set forth herein.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

It will be understood that, although the terms first, second, A, B, etc. may be used herein in reference to elements of the invention, such elements should not be construed as limited by these terms, unless the context indicates otherwise. For example, a first element could be termed a second element, and a second element could be termed a first element, without departing from the scope of the present invention. Herein, the term “and/or” includes any and all combinations of one or more referents.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein to describe embodiments of the disclosure is not intended to limit the scope of the invention. The articles “a,” “an,” and “the” are singular in that they have a single referent, however the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein are to be interpreted as is customary in the art to which this disclosure belongs. It will be further understood that terms in common usage should also be interpreted as is customary in the relevant art and not in an idealized or overly formal sense unless expressly so defined herein.

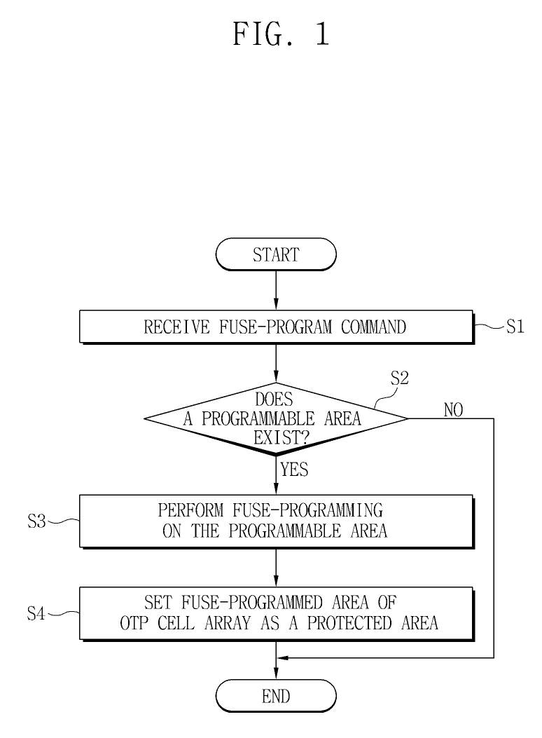

FIG. 1 is an exemplary flowchart illustrating a method of programming an OTP cell array, in accordance with one embodiment.

Referring to FIG. 1, the method of programming an OTP cell array including at least one of a protected area and a programmable area may include the following operations.

1) receiving a fuse-program command to initiate a fuse-programming operation (S1). Hereinafter, the fuse-programming operation may include steps beginning with a start command and continuing through a termination of a fuse-programming. Note that although the term “fuse-programming” operation is used, this term may refer to a situation where either fuses or anti-fuses are programmed.

2) checking whether a programmable area exists in the OTP cell array (S2).

3) performing a fuse-programming on the programmable area (S3). Hereinafter, the fuse-programming may refer to the step within the fuse-programming operation in which the one or more fuses are programmed (e.g., fuses are cut, or anti-fuses are connected).

4) setting the fuse-programmed area of the OTP cell array as a protected area (S4).

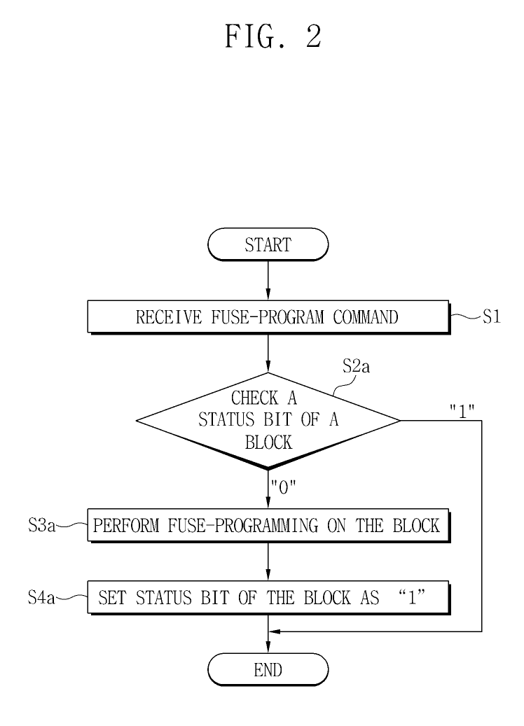

FIG. 2 is an exemplary flowchart illustrating a method of programming an OTP cell array, in accordance with another embodiment.

Referring to FIG. 2, the method of programming an OTP cell array including at least one of a protected area and a programmable area may include the following operations.

1) receiving a fuse-program command to initiate a fuse-programming operation (S1).

2) checking a status bit of a block (S2a).

3) performing a fuse-programming on the block (S3a).

4) setting the status bit of the block as “1” (S4a).

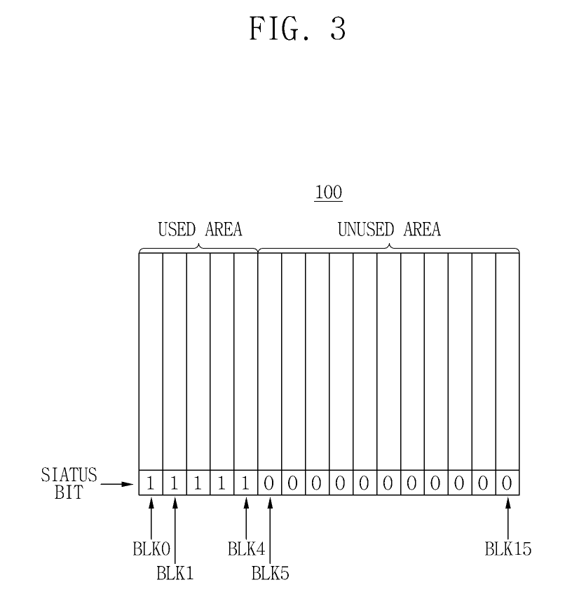

FIG. 3 is an exemplary diagram illustrating a schematic structure of an OTP cell array that operates according to the method of programming the OTP cell array shown in FIG. 2.

Referring to FIG. 3, the OTP cell array 100 may include a plurality of fuse blocks BLK0 to BLK15, and each of the fuse blocks BLK0 to BLK15 may include a status bit. For example, the OTP cell array 100 may include a used area comprised of fuse blocks BLK0 to BLK4 and an unused area comprised of fuse blocks BLK5 to BLK15. As shown in FIG. 3, the status bit of the used fuse blocks, i.e. programmed fuse blocks, may have logic “1”, and the status bit of the unused fuse blocks, i.e. unprogrammed fuse blocks, may have logic “0”. For example, a status bit of logic “1” may be read from the status bit to indicate that a fuse-programming has been performed and a status bit of logic “0” may be read from the status bit to indicate that a fuse-programming has not been performed.

The area of the OTP cell array 100 including the programmed fuse blocks (which may be referred to herein as a fuse-programmed area) may be set as a protected area that cannot be programmed any more. The fuse blocks of the OTP cell array 100 may not be programmed any more by setting a status bit of each of the fuse blocks as logic “1”. The status bit of each of the fuse blocks may be referred to as an indicator that indicates whether a block/area is permitted to be written, and may specifically indicate a permission status. In one embodiment, the fuse blocks may include anti-fuses, electric fuses or laser fuses.

The OTP cell array 100 of FIG. 3 may be an anti-fuse array, an electric fuse array, or a laser fuse array.

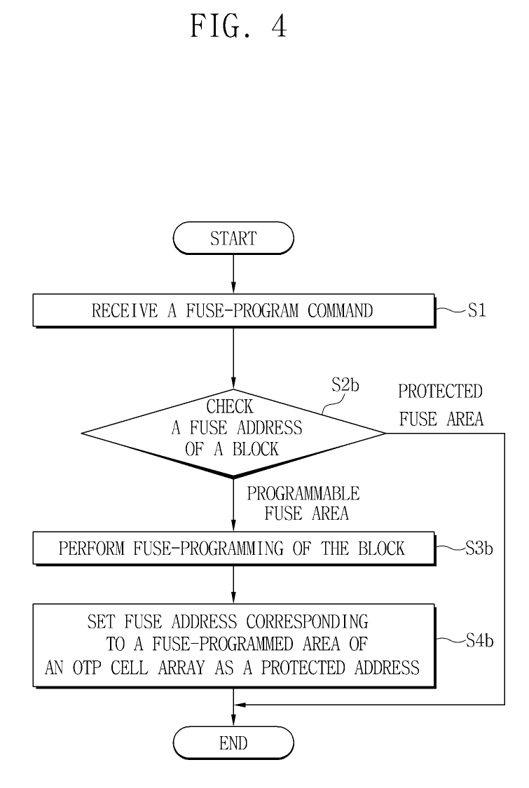

FIG. 4 is an exemplary flowchart illustrating a method of programming an OTP cell array, in accordance with still another embodiment.

Referring to FIG. 4, the method of programming an OTP cell array including at least one of a protected area and a programmable area may include the following operations.

1) receiving a fuse-program command to initiate a fuse-programming operation (S1).

2) checking a fuse address of a block (S2b).

3) performing a fuse-programming on the block (S3b).

4) setting the fuse address corresponding to a fuse-programmed area of the OTP cell array as a protected address (S4b).

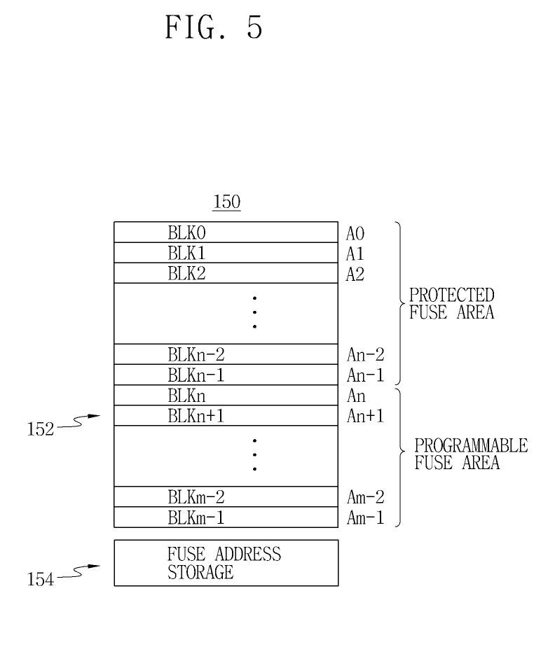

FIG. 5 is an exemplary diagram illustrating a schematic structure of an OTP cell array that operates according to the method of programming the OTP cell array shown in FIG. 4.

Referring to FIG. 5, the OTP cell array 150 may include a fuse cell array 152 including a plurality of memory blocks BLK0 to BLK(n−1) and BLKn to BLK(m−1), and each of the memory blocks BLK0 to BLK(n−1) and BLKn to BLK(m−1) may correspond to each of the fuse addresses A0 to A(n−1) and An to A(m−1). Further, the OTP cell array 150 may include a fuse address storage 154 that stores the fuse addresses A0 to A(n−1) and An to A(m−1). For example, the fuse cell array 152 may include a protected fuse area comprised of memory blocks BLK0 to BLK(n−1) and a programmable fuse area comprised of memory blocks BLKn to BLK(m−1). The OTP cell array 150 of FIG. 5 may set fuse addresses corresponding to the programmed memory blocks as protected addresses after programming the memory blocks. In one embodiment, the OTP cell array 150 of FIG. 5 may be an anti-fuse array, an electric fuse array, or a laser fuse array.

In one embodiment, in the OTP cell arrays 100 and 150 of FIG. 3 and FIG. 5, information necessary for an operation of a semiconductor memory device including the OTP cell arrays 100 and 150 may be stored. For example, information on fail cell addresses necessary for repairing defective cells of a memory cell array included in the semiconductor memory device, information on tuning of alternating current (AC) parameters, or information on tuning of direct current (DC) level may be stored in the OTP cell arrays 100 and 150. In the system on which a semiconductor memory device including the OTP cell array according to embodiments of the disclosure is mounted, the protected area which is already programmed may be prevented from being re-programmed.

Once particular fuse blocks of the OTP cell array are set as the protected area, the semiconductor memory device including the OTP cell arrays 100 and 150 may inform exterior devices such as a memory controller, etc. that the fuse blocks are set as protected areas.

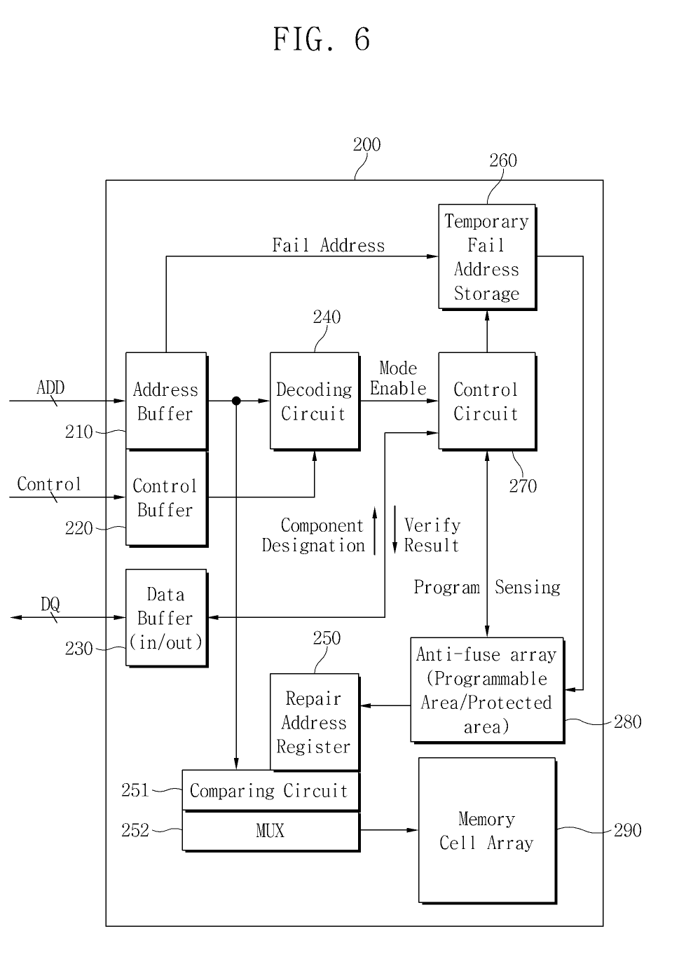

FIG. 6 illustrates an exemplary block diagram illustrating a semiconductor memory device including an OTP cell array, in accordance with certain embodiments.

Referring to FIG. 6, the semiconductor memory device 200 may include an address buffer 210, a control buffer 220, a data buffer 230, a decoding circuit 240, a repair address register 250, a comparing circuit 251, a multiplexer (Mux) 252, a temporary fail address storage (TFAS) 260, a control circuit 270, an anti-fuse array 280 which may be a non-volatile storage device, and a memory cell array 290.

For example, a fail address is received via the address buffer 210 and is temporarily stored in the temporary fail address storage 260. The temporary fail address storage 260 may be embodied as a register array, a static random access memory (SRAM), or a non-volatile memory. The decoding circuit 240 may receive and decode a control signal via the control buffer 220, and generate a mode enable signal. The control signal may include a read command, a write command, a pre-charge command, a mode register set signal, and the like. The control circuit 270 may be activated according to the mode enable signal, and store the fail address in the anti-fuse array 280. The control circuit 270 may sense the stored fail address to verify whether the fail address is accurately programmed. A result of the programming operation (verification result) is transmitted to the test device (not shown) via a data output pin DQ. The anti-fuse array 280, which is a non-volatile storage device, may be connected to the repair address register 250 configured to store the fail address. The repair address register 250 may be connected to the comparing circuit 251, which may be configured to compare the fail address with an external address. The comparing circuit 251 may be connected to the multiplexer (Mux) 252, which may be configured to select one of the fail address and the external address. Data received via the I/O data buffer 230 may be used as a chip selection signal (component designation) for selecting a chip among a plurality of chips on a memory module.

The anti-fuse array 280 of the semiconductor memory device 200 of FIG. 6 may have a protected area and a programmable area separate from the protected area, and the area including fuse blocks once programmed may be set as protected area. In the semiconductor memory device 200, the programmed fuse blocks may not be programmed any more by setting a status bit of each of the fuse blocks as logic “1”, or setting fuse addresses corresponding to the programmed fuse blocks as protected addresses.

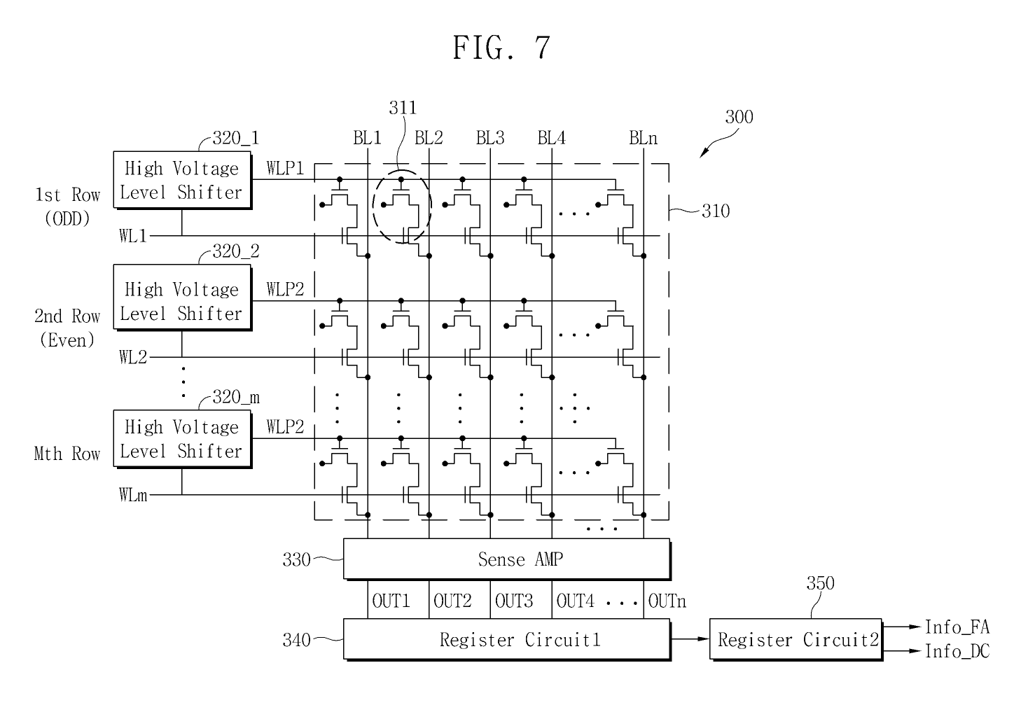

FIG. 7 is an exemplary diagram illustrating an anti-fuse array included in the semiconductor memory device of FIG. 6, in accordance with one embodiment.

Referring to FIG. 7, the anti-fuse array circuit 300 may include a fuse array 310 on which a plurality of anti-fuses 311 may be disposed, level shifters 320_1 to 320_{—}m that may generate a high voltage to change resistance states of the plurality of anti-fuses 311, and a sense amplifier 330 that may sense/amplify information stored in the fuse array 310. Further, the anti-fuse array circuit 300 may include a first register circuit 340 and a second register circuit 350 to store fuse data generated when information stored in the anti-fuse array circuit 300 is read. Each of the first register unit 340 and the second register unit 350 may be embodied in a shift register having a plurality of registers.

The fuse array 310 includes the plurality of anti-fuses, and the anti-fuses may have a characteristic that changes from a high resistance state to a low resistance state in response to an electric signal, for example a high voltage signal.

Though, the fuse array 310 including anti-fuses are shown in FIG. 7, the fuse array 310 may include laser fuses, the connections of which are controlled through laser irradiation, or may include electric fuses, the connections of which are controlled according to an electrical signal.

In the following embodiment, it is assumed that the fuse array 310 is an anti-fuse array circuit 300 including anti-fuses. Also, information stored in the anti-fuses or data read from the anti-fuses will be hereinafter referred to as fuse data.

The fuse array 310 may have an array structure in which anti-fuses 311 are disposed at intersections of a plurality of rows and a plurality of columns. For example, if the fuse array 310 may include m rows and n columns, then the fuse array 310 includes m×n anti-fuses 311. The fuse array 310 may include m word lines WL1 to WLm for accessing the anti-fuses 311 disposed in the m rows, and n bit lines BL1 to BLn disposed to correspond to the n columns to transfer information read from the plurality of anti-fuses 311.

The anti-fuse array circuit 300 may store various information related to an operation of a semiconductor memory device (200 in FIG. 6) including the anti-fuse array 300. For example, the anti-fuse array circuit 300 may store a plurality of pieces of setting information for setting an operating environment of the semiconductor memory device (200 in FIG. 6). The plurality of pieces of setting information may be programmed by changing the states of the plurality of anti-fuses 311 by supplying voltage signals WLP1 to WLPm provided from the level shifters 320_1 to 320_{—}m to the fuse array 310. Information is stored in the plurality of anti-fuses 311 by changing the plurality of anti-fuses 311 from the high resistance state to the low resistance state by a fuse-programming operation, unlike a general fuse circuit, e.g., a laser fuse circuit or an electric fuse circuit, etc. The plurality of anti-fuses 311 may have a structure in which a dielectric layer is disposed between two conductive layers, i.e., a capacitor structure. The plurality of anti-fuses 311 may be programmed by applying high voltage between the two conductive layers, and breaking down the dielectric layer.

After the fuse array 310 is programmed, a read operation on the fuse array 310 may be performed, together with a start of driving of the semiconductor memory device 200. The read operation on the fuse array 310 may be simultaneously performed with the start-up of the semiconductor memory device 200, or after a predetermined set time from the driving of the semiconductor memory device 200. In the fuse array 310, a word line selection signal may be provided via the word lines WL1 to WLm, and information stored in a selected anti-fuse 311 may be provided to the sense amplifier 330 via the bit lines BL1 to BLn. According to characteristics of the array structure, the information stored in the fuse array 310 may be randomly accessed by driving the word lines WL1 to WLm and the bit lines BL1 to BLn.

For example, as the word lines WL1 to WLm are sequentially driven, the plurality of anti-fuses 311 may be sequentially accessed from a first row to an m-th row in the fuse array 310. The information that is sequentially accessed from the plurality of anti-fuses 311 may be provided to the sense amplifier 330. The sense amplifier 330 may include one or more sense amplifier circuits. For example, when the fuse array 310 includes n columns, the sense amplifier 330 may include n sense amplifier circuits corresponding to the n columns. The n sense amplifier circuits may be connected to the n bit lines BL1 to BLn, respectively. Two sense amplifier circuits may be disposed to correspond to each of the n bit lines BL1 to BLn. For example, an odd-numbered sense amplifier circuit and an even-numbered sense amplifier circuit may be disposed to correspond to a first bit line BL1. The odd-numbered sense amplifier circuit may sense/amplify and output information stored in the anti-fuses 311 connected to odd-numbered word lines WL1, WL3, WL5, . . . , and WLm. The even-numbered sense amplifier circuit may sense/amplify and output information stored in the anti-fuses 311 connected to even-numbered word lines WL2, WL4, WL6, . . . , and WLm−1. However, the disclosure is not limited thereto, and sense amplifier circuits may be arranged in any of various shapes. For example, only one sense amplifier circuit may be arranged to correspond to one bit line, or three or more sense amplifier circuits may be arranged to correspond to one bit line.

The sense amplifier 330 may sense/amplify and output the information accessed from the fuse array 310. The sensed/amplified information may be fuse data OUT1 to OUTn that is actually used to set an operating environment of the semiconductor memory device 200. As described above, in case two sense amplifier circuits are provided to correspond to each bit line, actually, a piece of fuse data, e.g., first fuse data OUT1, may include an odd-numbered piece of fuse data and an even-numbered piece of fuse data.

The fuse data OUT1 to OUTn output from the sense amplifier 330 may be provided to the first register circuit 340. The first register circuit 340 may be embodied as a shift register in which a plurality of registers is connected in series to sequentially deliver a signal. Also, the number of registers included in the first register circuit 340 is less than that of the plurality of anti-fuses 311 included in the fuse array 310. Also, the number of registers included in the first register circuit 340 may be determined based on that of columns included in the fuse array 310. For example, when the fuse array 310 includes n columns, the first register circuit 340 may include n registers. Otherwise, as described above, when two sense amplifier circuits are arranged to correspond to each bit line, the first register unit 340 may include 2×n registers.

The first register circuit 340 may receive the fuse data OUT1 to OUTn in units of the rows in the fuse array 310. For example, when one row is selected from among the rows of the fuse array 310, fuse data OUT1 to OUTn stored in anti-fuses 311 connected to a word line of the selected row may be provided in parallel to the first register circuit 340. The first register circuit 340 may provide the fuse data OUT1 to OUTn to the second register circuit 350 by shifting the provided fuse data OUT1 to OUTn in units of bits. The second register circuit 350 may be embodied as a shift register in which a plurality of registers is connected in series to sequentially deliver a signal. The number of registers included in the second register circuit 350 may be equal to that of the plurality of anti-fuses 311 included in the fuse array 310. Fuse data OUT1 to OUTn stored in the second register circuit 350 may be used as information for setting an operating environment of the semiconductor memory device 200. For example, one portion of the fuse data OUT1 to OUTn stored in the second register circuit 350 may be used as information Info_FA for replacing a memory cell (not shown) included in the semiconductor memory device 200 with a redundant memory cell, and another portion of the fuse data OUT1 to OUTn may be used as trimming information Info_DC for adjusting a voltage level generated in the semiconductor memory device 200.

To store the fuse data OUT 1 to OUTn from the fuse array 310, the followings may be used, in the preferred embodiment: (i) registers connected to the sense amplifier 330 may be used to temporarily store the fuse data OUT1 to OUTn; and (ii) registers coupled to various circuit blocks of the semiconductor memory device 200, e.g., a row and column decoder or a direct-current (DC) voltage generator, may be used to provide fuse data OUT1 to OUTn to the circuit blocks.

In accordance with an exemplary embodiment, the first register circuit 340 may receive the fuse data OUT1 to OUTn from the sense amplifier 330, and transmit the fuse data OUT1 to OUTn to the second register circuit 350 adjacently coupled to these circuit blocks. In particular, in this embodiment, the fuse array 310 may have the array structure, the first register circuit 340 may include the registers, the number which may correspond to that of columns included in the fuse array 310. Thus, the number of registers included in the first register circuit 340 may be less than that of the plurality of anti-fuses 311 included in the fuse array 310. For example, when one sense amplifier circuit is arranged to correspond to each bit line, the first register circuit 340 may include n sense amplifier circuits. Thus, the number of registers in the first register circuit 340 related to the fuse data OUT1 to OUTn may be satisfied as not m×n but only n. In particular, even if a large number of anti-fuses 311 are included in the fuse array 310, the number of registers included in the first register circuit 340 may be limited to n, depending on the structure of the fuse array unit 310. Accordingly, the number of registers included in the first register circuit 340 may be prevented from being proportionally increased.

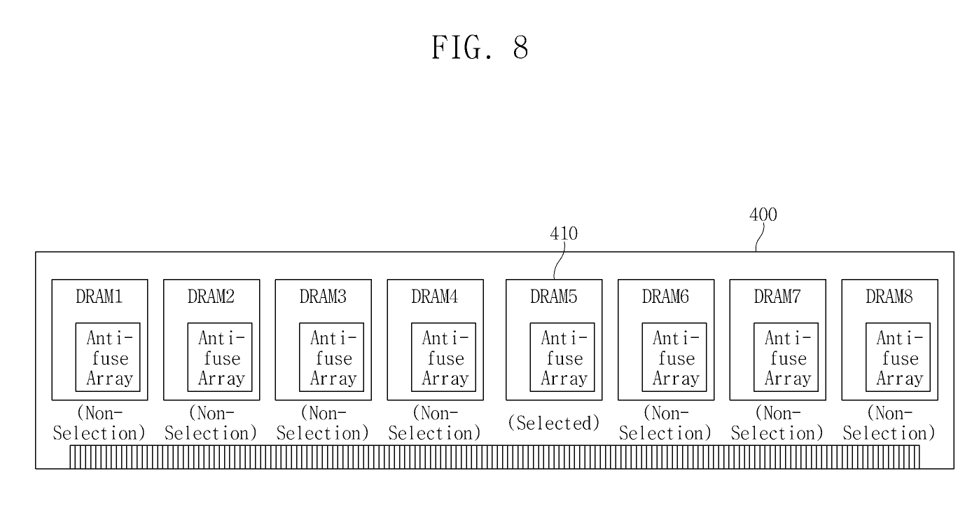

FIG. 8 is an exemplary diagram illustrating a structure of a memory module including a semiconductor memory device, in accordance with certain embodiments.

Referring to FIG. 8, the module 400 may include one or more memory devices disclosed above. For example, the module 400 may include eight DRAMs. Each of the DRAMs 410 may include an anti-fuse array, which is a non-volatile storage device. When a fail address is stored in a DRAMS, for example, a memory controller may select the DRAMS by transmitting data ‘0’ to only the DRAMS. The anti-fuse array included in each of the DRAMs may be used to store a generated fail address in the DRAM. A command and an address may be shared by the eight DRAMs.

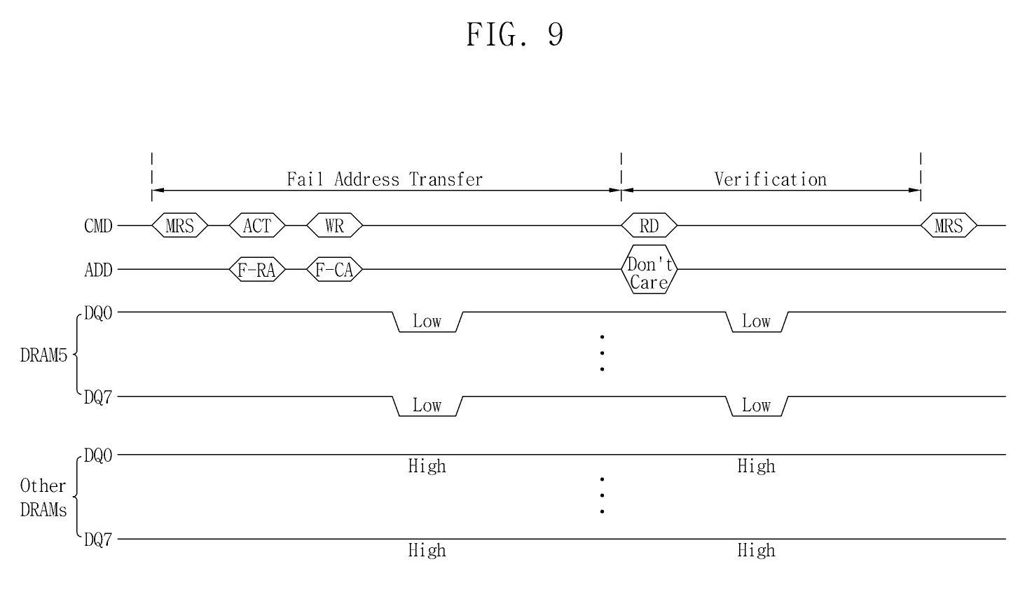

FIGS. 9 and 10 are exemplary timing diagrams illustrating transmission of a fail address in the semiconductor memory device of FIG. 6, in accordance with certain embodiments.

Referring to FIG. 9, a mode set register command MRS, an active command ACT, a read command RD, and a write command WR may be received via a command line CMD. A row fail address F-RA and a column fail address F-CA may be received via an address line ADD. Referring to FIGS. 8 and 9, the DRAMS may be selected among the eight DRAMs by receiving only data ‘0’ (logic low) via a data pin DQ. Since data received via data pins DQ0 to DQ7 all becomes logic ‘low,’ a fail address may be thus stored in the anti-fuse array, which is a non-volatile storage device included in the DRAMS. After the mode register set command MRS, the active command ACT, and the write command WR are sequentially input and the row fail address F-RA and the column fail address F-CA are input, data ‘0’ may be supplied as final chip selection data via the data pin DQ and the fail address may be stored in the anti-fuse array. This period may be a fail address transfer period. A period between when the programmed fail address is read according to the read command RD and when another mode register set command MRS is received may be a verification period. A verification process is completed when the other mode register set command MRS is input after the read command is received.

The timing diagram of FIG. 10 may be similar to the timing diagram of FIG. 9, except that a memory cell corresponding to a fail address is repaired by receiving only a row fail address F-RA via an address line ADD. Also, when a verification process is performed to read the fail address again, the verification process is completed according to a pre-charge command and a repair operation may be finished.

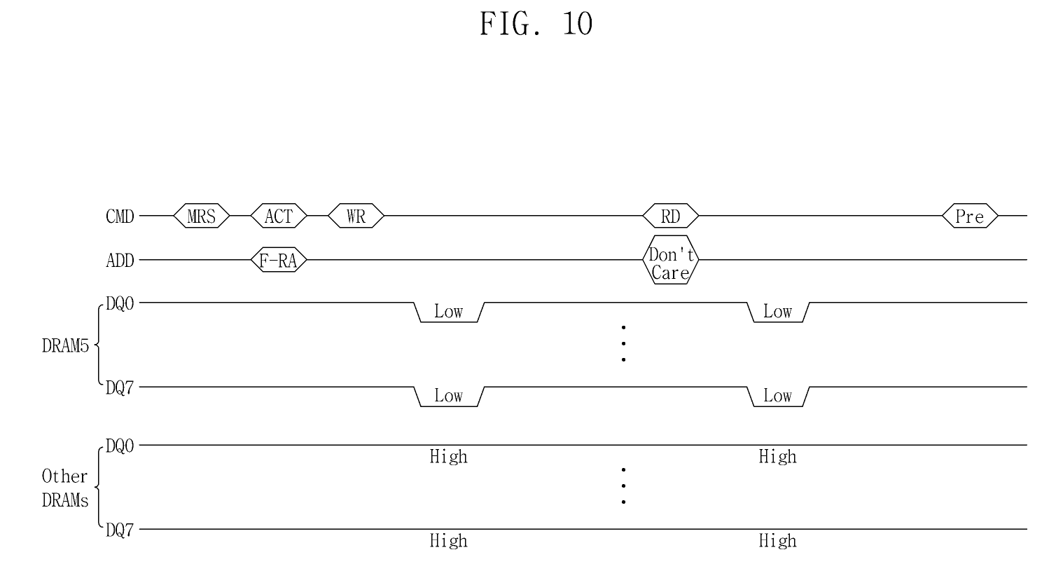

FIG. 11 is a perspective view of an example of a stacked semiconductor device including a semiconductor memory device in accordance with certain embodiments.

Referring to FIG. 11, the stacked semiconductor device 600 may include an interface chip 610, and memory chips 620, 630, 640 and 650 which are electrically connected through through-substrate vias (e.g., through-silicon vias) 660. Although the through-silicon vias 660 disposed in two rows are shown in FIG. 11, the stack semiconductor device 600 may include any number of through-silicon vias.

Each of the memory chips 620, 630, 640 and 650 included in the stacked semiconductor device 600 may include OTP cell array according to disclosed embodiments. The interface chip 610 may perform an interface function between the memory chips 620, 630, 640 and 650 and external devices.

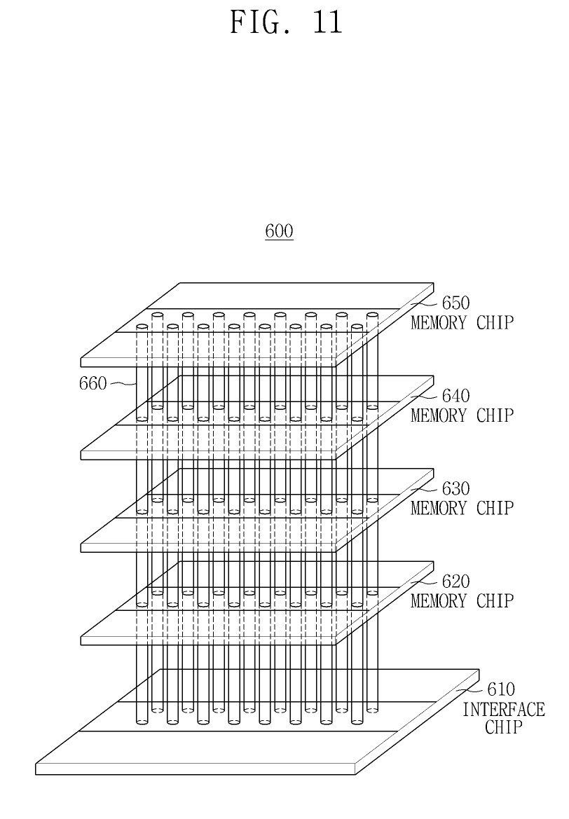

FIG. 12 is a diagram of an example of a memory system including a semiconductor memory device in accordance with certain embodiments.

Referring to FIG. 12, the memory system 700 may include a motherboard 731, a chip set (or a controller) 740, slots 735_1 and 735_2, memory modules 750 and 760, and transmission lines 733 and 734. Buses 737 and 739 may connect the chip set 740 with the slots 735_1 and 735_2. A terminal resistor Rtm may terminate each of the buses 737 and 739 on a PCB of the motherboard 731.

For convenience, in FIG. 12, only two slots 735_1 and 735_2 and two memory modules 750 and 760 are shown. However, the memory system 700 may include an arbitrary number of slots and memory modules.

The chip set 740 may be mounted on the PCB of the motherboard 731, and control the operation of the memory system 700. The chip set 540 may include connectors 741_1 and 741_2 and converters 743_1 and 743_2.

The converter 743_1 may receive parallel data generated by the chip set 740, convert the parallel data to serial data, and output the serial data to the transmission line 733 via the connector 741_1. The converter 743_1 may receive serial data via the transmission line 733, convert the serial data to parallel data, and output the parallel data to the chip set 740.

The converter 743_2 may receive parallel data generated by the chip set 740, convert the parallel data to serial data, and output the serial data to the transmission line 734 via the connector 741_2. The converter 743_2 may receive serial data via the transmission line 734, convert the serial data to parallel data, and output the parallel data to the chip set 740. The transmission lines 733 and 734 included in the memory system 700 may be a plurality of optical fibers.

The memory module 750 may include a plurality of memory devices 755_1 to 755_{—}n, a first connector 757, a second connector 751, and a converter 753. The memory module 760 may include a plurality of memory devices 765_1 to 765_{—}n, a first connector 757′, a second connector 751′, and a converter 753′.

The first connector 757 may transfer low-speed signals received from the chip set 740 to the memory devices 755_1 to 755_{—}n, and the second connector 751 may be connected to the transmission line 733 for transferring high-speed signals.

The converter 753 may receive serial data via the second connector 751, convert the serial data to parallel data, and output the parallel data to the memory devices 755_1 to 755_{—}n. Further, the converter 753 may receive parallel data from the memory devices 755_1 to 755_{—}n, convert the parallel data to serial data, and output the serial data to the second connector 51.

The memory devices 755_1 to 755_{—}n and 765_1 to 765_{—}n may include a semiconductor memory device according to disclosed embodiments. Therefore, the memory devices 755_1 to 755_{—}n and 765_1 to 765_{—}n may include OTP cell array according to disclosed embodiments. The memory devices 755_1 to 755_{—}n and 765_1 to 765_{—}n may be a volatile memory chip such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof.

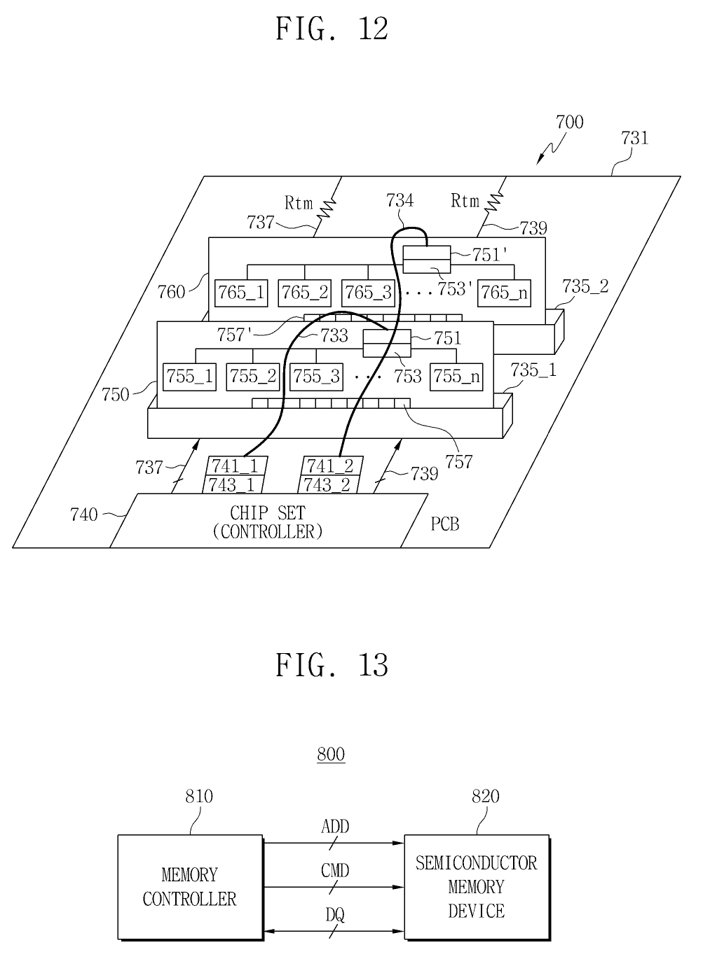

FIG. 13 is a block diagram of another example of a memory system 800 including a semiconductor memory device in accordance with certain embodiments.

Referring to FIG. 13, the memory system 800 may include a memory controller 810 and a semiconductor memory device 820.

The memory controller 810 may generate address signals ADD and command signals CMD and provides the address signals ADD and the command signals CMD to the semiconductor memory device 820 through buses. Data DQ may be transmitted from the memory controller 810 to the semiconductor memory device 820 through the buses, or transmitted from the stacked semiconductor memory device 820 to the memory controller 810 through the buses.

The semiconductor memory device 820 may include an OTP cell array in accordance with disclosed embodiments.

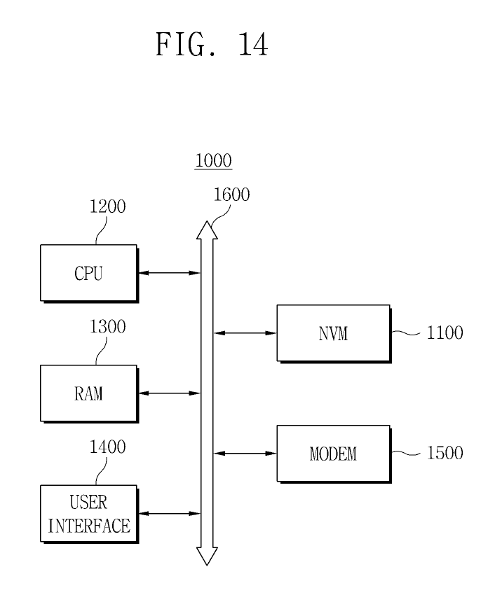

FIG. 14 is a block diagram of an example of an electronic system including a semiconductor memory device in accordance with certain embodiments.

Referring to FIG. 14, the electronic system 1000 in accordance with embodiments may include a central processing unit (CPU) 1200 electrically connected to a system bus 1600, a random access memory (RAM) 1300, a user interface 1400, a MODEM 1500 such as a baseband chipset, and a non-volatile memory device (NVM) 1100.

The NVM 1100 and the RAM 1300 may store or output data, and include various logic circuits therein. When the electronic system 1000 according to example embodiments is a mobile device, a battery that supplies operating voltage to the electronic system 1000 may be additionally provided (not shown). Although not drawn in FIG. 14, the electronic system 1000 may be further provided with an application chipset, a camera image processor, and a mobile DRAM, that is obvious to ordinary skill in the art. The NVM 1100 is, for example, may comprise a solid state drive/disk (SSD) including non-volatile memory devices for storing data. Further, the NVM 1100 may comprise a fusion flash memory in which a static random access memory (SRAM), a NAND flash memory and a NOR interface logic are combined.

A semiconductor device according to example embodiments may be applied to a part of the electronic system 1000. For example, when the electronic system 1000 is booting, the example embodiments of the inventive concepts may be applied to set operating environments. Each of the NVM 1100 and the RAM 1300 may include a non-volatile memory cell array, be programmed by a method of programming the OTP cell array. The OTP cell array may be divided into a protected area and a programmable area, and an area including programmed fuse blocks may be set as the protected area. It may be possible to set a status bit of each of fuse blocks included in the non-volatile memory 1100 or the RAM 1300 as logic “1”, or fuse addresses corresponding to the programmed fuse blocks as protected addresses. Accordingly, the programmed fuse blocks may not be programmed any more.

The semiconductor device and/or the system according to example embodiments of the inventive concepts may be mounted using various types of packages. For example, the semiconductor device and/or the system may be mounted using packages such as a Package on Package (POP), a Ball grid arrays (BGAs), a Chip scale packages (CSPs), a Plastic Leaded Chip Carrier (PLCC), a Plastic Dual In-Line Package (PDIP), a Die in Waffle Pack, Die in Wafer Form, a Chip On Board (COB), a Ceramic Dual In-Line Package (CERDIP), a Plastic Metric Quad Flat Pack (MQFP), a Thin Quad Flatpack (TQFP), a Small Outline Integrated Circuit (SOIC), a Shrink Small Outline Package (SSOP), a Thin Small Outline Package (TSOP), a Thin Quad Flatpack (TQFP), a System In Package (SIP), a Multi Chip Package (MCP), a Wafer-level Fabricated Package (WFP), and a Wafer-Level Processed Stack Package (WSP).

The disclosed embodiments may be applied to a semiconductor device, and particularly, to a semiconductor memory device and a memory system including the semiconductor memory device.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims.

What is claimed is:

1. A method of programming a memory device including a one-time programmable (OTP) cell array configured to include at least one of a protected area and a programmable area, the method comprising:
receiving a fuse-program command to initiate a fuse-programming operation;
checking whether the programmable area exists in the OTP cell array;
terminating the fuse-programming operation when the OTP cell array does not include the programmable area;
performing a fuse-programming operation on the programmable area when the OTP cell array includes the programmable area thereby programming fuses to create a fuse-programmed area;
setting the fuse-programmed area of the OTP cell array as the protected area.

2. The method according to claim 1, wherein the protected area is a programmed area.

3. The method according to claim 1, wherein the checking whether the programmable area exists in the OTP cell array comprises checking a status bit of each block of a plurality of blocks of the OTP cell array.

4. The method according to claim 3, further comprising:
determining a first area including one or more blocks that have the status bit of “0” as the programmable area; and
determining a second area including one or more blocks that have the status bit of “1” as the protected area.

5. The method according to claim 4, further comprising:
performing a fuse-programming on the first area; and
setting the status bit of the first area as “1” after the performing the fuse-programming on the first area.

6. The method according to claim 1, wherein the checking whether the programmable area exists in the OTP cell array comprises checking a fuse address of each block of a plurality of blocks of the OTP cell array.

7. The method according to claim 1, wherein the setting the fuse-programmed area of the OTP cell array comprises:
after the performing the fuse-programming on the programmable area, setting a fuse address corresponding to the fuse-programmed area of the OTP cell array as a protected address.

8. The method according to claim 1, further comprising:
setting a status bit having a first value for one or more blocks to designate a protected area; and
setting a status bit having a second value different from the first value for one or more blocks to designate a programmable area.

9. The method according to claim 1, wherein the OTP cell array includes a plurality of non-volatile memory cells.

10. The method according to claim 1, wherein the OTP cell array includes a plurality of anti-fuse cells or a plurality of electric fuse cells.

11. A semiconductor memory device, comprising:
a memory cell array configured to store data; and
a one-time programmable (OTP) cell array including a protected area and a programmable area separate from the protected area, the OTP cell array configured to store a fail address corresponding to a defective memory cell of the memory cell array,
wherein the OTP cell array is configured to perform a fuse-programming operation on one or more blocks of the programmable area of the OTP cell array to create a fuse-programmed area, and set the fuse-programmed area of the OTP cell array as part of the protected area.

12. The device according to claim 11, wherein the OTP cell array includes a plurality of area each area having a status bit that indicates the programmable area or the protected area.

13. The device according to claim 11, further comprising a temporary fail-address storage configured to temporarily store the fail address.

14. The device according to claim 13, further comprising an address buffer configured to buffer the fail address and provide the buffered fail address to the temporary fail-address storage.

15. The device according to claim 11, wherein the semiconductor memory device is a stacked memory device in which a plurality of chips communicates data and control signals through a through-silicon-via (TSV).

16. A method of programming a memory device including a one-time programmable (OTP) cell array, the method comprising:
initiating a fuse-programming operation;
reading an indicator that indicates whether a particular area of the OTP cell array is permitted to be written to or not;
performing programming in the particular area when the indicator indicates that the particular area is permitted to be written to; and
terminating the fuse-programming operation without performing the programming when the indicator indicates that the particular area is not permitted to be written to.

17. The method according to claim 16, wherein the indicator includes a status of “0” or “1” or a protected address.

18. The method according to claim 17, wherein the OTP cell array stores the indicator.

19. The method according to claim 16, further comprising:
after performing programming in the particular area, designating the particular area as a protected area indicating that is not permitted to be written to.

20. The method according to claim 16, wherein the OTP cell array includes a plurality of anti-fuse cells or a plurality of electric fuses.
